(19) United States
(12) Patent Application Publication
(10) Pub. No.: US 2012/0327965 A1
(43) Pub. Date: Dec. 27, 2012

(54) SEMICONDUCTOR LASER ELEMENT, METHOD OF MANUFACTURING SEMICONDUCTOR LASER ELEMENT, AND OPTICAL MODULE

(76) Inventors: Kazunori Shinoda, Musashino (JP); Koichiro Adachi, Musashino (JP); Shinji Tsuji, Hidaka (JP); Masahiro Aoki, Kokubunji (JP)

(21) Appl. No.: 13/521,555

(22) PCT Filed: Feb. 2, 2010
(86) PCT No.: PCT/JP2010/051408

§ 371 Date: Jul. 11, 2012

(51) Int. Cl. H01S 5/028; H01S 5/024; H01L 21/02

(52) U.S. Cl. 372/36; 438/29; 372/45.01; 257/E21.002

(57) ABSTRACT

In order to provide a semiconductor laser element or an integrated optical device with high reliability, a horizontal-cavity semiconductor laser or an optical module includes a deeply dug DBR mirror serving as a cavity mirror, the deeply dug DBR mirror being composed of a material that is lattice-matched to a substrate and that has a band gap energy that does not absorb light emitted from an active layer.

### TECHNICAL FIELD

The present invention relates to a semiconductor laser element and an optical module using the semiconductor laser element.

### BACKGROUND ART

Semiconductor lasers used as light sources for optical communication and optical information recording use cavity mirrors in order to achieve lasing by feeding back light amplified by stimulated emission. Various structures have been used as a cavity mirror for a semiconductor laser.

Examples of techniques that enable a reflector for a semiconductor laser to be formed on a semiconductor substrate using only wafer processes include the deeply-etched multilayer DBR (Distributed Bragg Reflector) technology. The deeply-etched multilayer DBR technology is a technology that allows a plurality of deep grooves to be formed in an end portion of the resonator using an etching technology, thereby forming a multilayer DBR mirror consisting of semiconductor and air in an extension of the active region. Using this technology can achieve a laser fabrication process that is superior in terms of the mass production efficiency, the integration degree, and the degree of design freedom of the cavity length because a cavity mirror can be formed using only wafer processes.

Cavity mirror structures referred to as DBRs fall into two general classes. The first class has a structure in which a waveguide structure into which no current is injected is formed in a direction in which the waveguide of a horizontal-cavity laser including an active layer extends and a grating is formed in a part of, above, or below the waveguide structure into which no current is injected. Such a DBR is referred to hereinafter as a waveguide DBR. The second class relates to the present invention, and has a structure referred to as a multilayer DBR. A multilayer DBR is a DBR in which two kinds of films having an optical film thickness corresponding to one fourth the wavelength are stacked one over another repeatedly (other film thicknesses such as three fourths the wavelength may also be used), and is characterized in that a surface-like periodic structure is formed so as to cover the entire extension of the optical waveguide in a direction in which the light is output. When such a DBR is used as a cavity mirror in a vertical cavity surface-emitting laser, a structure in which two kinds of films are stacked one over another repeatedly so as to cover the wafer surface may be employed. Examples of such a structure include semiconductor multilayer reflectors and dielectric multilayer reflectors. On the other hand, when a multilayer DBR is used as a cavity mirror in a horizontal-cavity laser, it is common practice to form deep grooves in a semiconductor wafer using an etching technology, thereby forming a periodic structure consisting of film-like semiconductor membranes and grooves extending vertically. A DBR having such a structure is referred to hereinafter as a deeply-etched multilayer DBR. A deeply-etched multilayer DBR is sometimes referred to as a vertical multilayer reflector due to its structural nature, and is sometimes also referred to as a semiconductor/air Bragg reflector.

Examples of semiconductor lasers using a deeply-etched multilayer DBR are disclosed in Nonpatent Literature 1, which specifically discloses the operational characteristics of a 0.98 μm wavelength band InGaAs/AlGaAs short cavity laser on a GaAs substrate and a 1.55 μm wavelength band InGaAsP/InP short cavity laser on an InP substrate using as the cavity mirror a multilayer DBR consisting of semiconductor and air formed using the EB (Electron Beam) lithography and the reactive ion beam etching technology. Nonpatent Literature 2 also discloses the light-current characteristics of a 1.5 μm wavelength band InGaAsP/InP laser on an InP substrate using as the cavity mirror a multilayer DBR; the multilayer DBR is fabricated by forming a DBR consisting of semiconductor and air using the EB lithography and the reactive ion etching technology and filling the air grooves with BCB (Benzocyclobutene) polymer.

### CITATION LIST

### Nonpatent Literature

Nonpatent Literature 1: Japanese Journal of Applied Physics, Part 1, Vol. 35, No. 2B, page 1390 (1996)
Nonpatent Literature 2: Electronics Letters, Vol. 35, No. 16, page 1336 (1999)

### SUMMARY OF INVENTION

### Technical Problem

There has been a problem in that it is difficult to achieve a cavity mirror having a high reflectivity when the existing deeply-etched multilayer DBR technology is used to form a cavity mirror. The reason why it is difficult to achieve a high reflectivity cavity mirror using the existing deeply-etched multilayer DBR technology will be described with reference to FIGS. 1(a) to 1(d) below. FIGS. 1(a) to 1(d) are diagrams showing an example of a fabrication process of an existing semiconductor laser using deeply-etched multilayer DBRs as the cavity mirrors. Here, description will be given through an exemplary 1.3 μm wavelength band laser including an InGaAlAs multiple Quantum Well (MQW) active layer formed on an InP substrate. The figures are sectional views taken along the direction which is parallel to the optical axis of the laser element.

According to this fabrication process, a substrate having a so-called buried hetero-structure (BH) is first provided by forming an InGaAlAs MQW active layer 12 on an n-type InP substrate 11, forming thereon a p-type InP cladding layer 13 and a p-type InGaAs contact layer 14, and then performing the ordinary mesa etching and buried regrowth processes that are not shown (FIG. 1(a)). Then, using the ordinary thermal CVD (Chemical Vapor Deposition) and EB lithography, a silicon dioxide mask pattern 15 having a width corresponding to one fourth the optical wavelength is formed (FIG. 1(b)). Thereafter, the dry etching technology or a combination of the dry etching and wet chemical etching technologies is used to etch the semiconductor layers up to below the active layer section, thereby forming multilayer DBRs consisting of semiconductor and air (FIG. 1(c)). Finally, the silicon dioxide mask 15 is removed, and a p-electrode 16 and an n-electrode 17 are formed using the ordinary resistance heating evaporation, thus resulting in the element being completed (FIG. 1(d)). However, because the semiconductor layers that are etched in the etching process shown in FIG. 1(c) are not made of a single material, but has a structure consisting of a plurality of different materials stacked one over another, i.e., an InGaAs layer, an InP layer, an InGaAlAs MQW layer, and an InP layer, the side wall shape of the grooves cannot be processed into a perfectly vertical and smooth flat shape, thus resulting in an irregular shape being obtained reflecting the material composition dependency of the lateral etching rate. For this reason, it is difficult to obtain a high reflectivity due to optical scattering loss caused by the irregular shape because the grooves having the irregular side walls are used as the multilayer DBRs. Furthermore, in the completed semiconductor laser shown in FIG. 1(d), the active layer portions remaining in the multilayer DBR sections act as absorbers although no electrodes are formed in the multilayer DBR sections and therefore no current is injected thereinto. This will cause another problem in that the reflectivity of the multilayer DBR sections is further reduced.

In addition, when the active layer is exposed so as to contact with air or dielectric as shown in FIG. 1(d), crystal defects may be generated in the end portions of the active layer. This will cause a further problem in that the reliability associated with the life time of the laser is reduced.

In this manner, existing deeply-etched multilayer DBRs have a problem in that a cavity mirror having a high reflectivity cannot be obtained because the semiconductor membranes of the DBR sections are formed by etching the waveguide including the active layer, and as a result, the reliability of the laser is reduced.

An object of the present invention is to provide a reliable semiconductor laser.

### Solution to Problem

To summarize representative means for achieving the object of the invention, a semiconductor laser element includes: a semiconductor substrate; a mesa stripe including a semiconductor layer, an active layer, a cladding layer, and a contact layer on the semiconductor substrate; and a reflector consisting of multilayer films on the semiconductor substrate in at least one of directions in which the mesa stripe extends. The semiconductor laser element is characterized in that the multilayer films are arranged at an interval corresponding to an integer multiple of one fourth the optical wavelength of light output from the active layer and the band gap wavelength of the multilayer films is shorter than the band gap wavelength of the active layer.

### Advantageous Effects of Invention

The present invention can improve the reliability of a semiconductor laser.

### BRIEF DESCRIPTION OF DRAWINGS

FIGS. 1(a) to 1(d) are element sectional views showing a process for fabricating an existing semiconductor laser.

FIGS. 2(a) to 2(f) are element sectional views showing a process for fabricating a semiconductor laser according to a first embodiment.

FIGS. 3(a) to 3(f) are element sectional views showing a process for fabricating a semiconductor laser according to a variant of the first embodiment.

FIG. 4 is a perspective view showing a laser element according to a second embodiment with a portion of the laser element broken away.

FIG. 5 is a sectional view of the laser element according to the second embodiment taken along the optical axis direction.

FIG. 6 is a bottom view of the laser element according to the second embodiment.

FIG. 7 is a sectional view of the laser element according to the second embodiment taken along a direction perpendicular to the optical axis.

FIGS. 8(a) to 8(g) are sectional views showing a method for fabricating the laser element according to the second embodiment.

FIG. 9 is a diagram showing the structure of an optical transmitter module according to a third embodiment.

FIG. 10 is a diagram showing the structure of a can module according to the third embodiment.

FIG. 11 is a diagram showing the structure of an optical transceiver module according to a fourth embodiment.

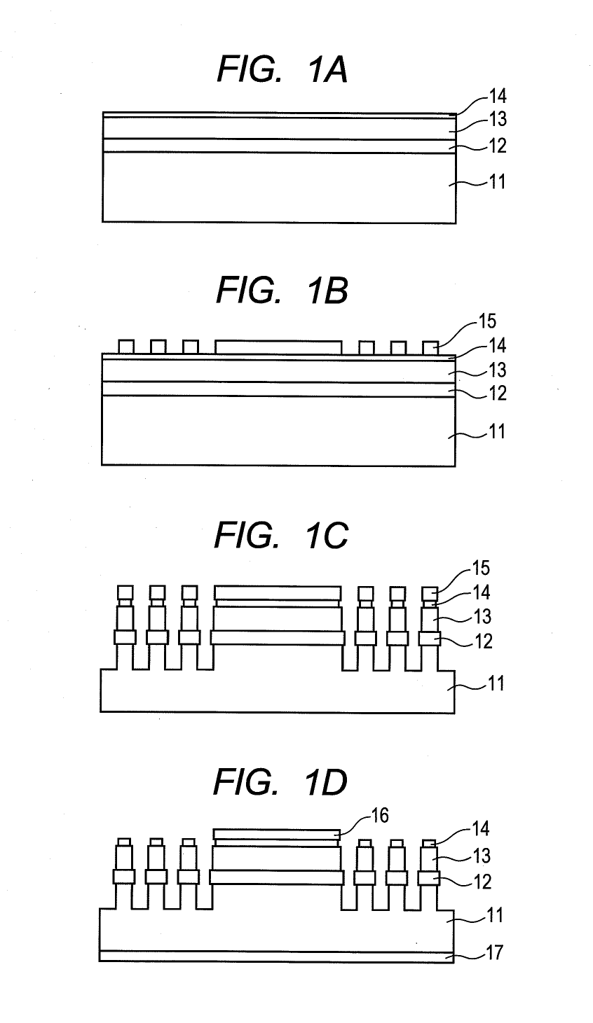

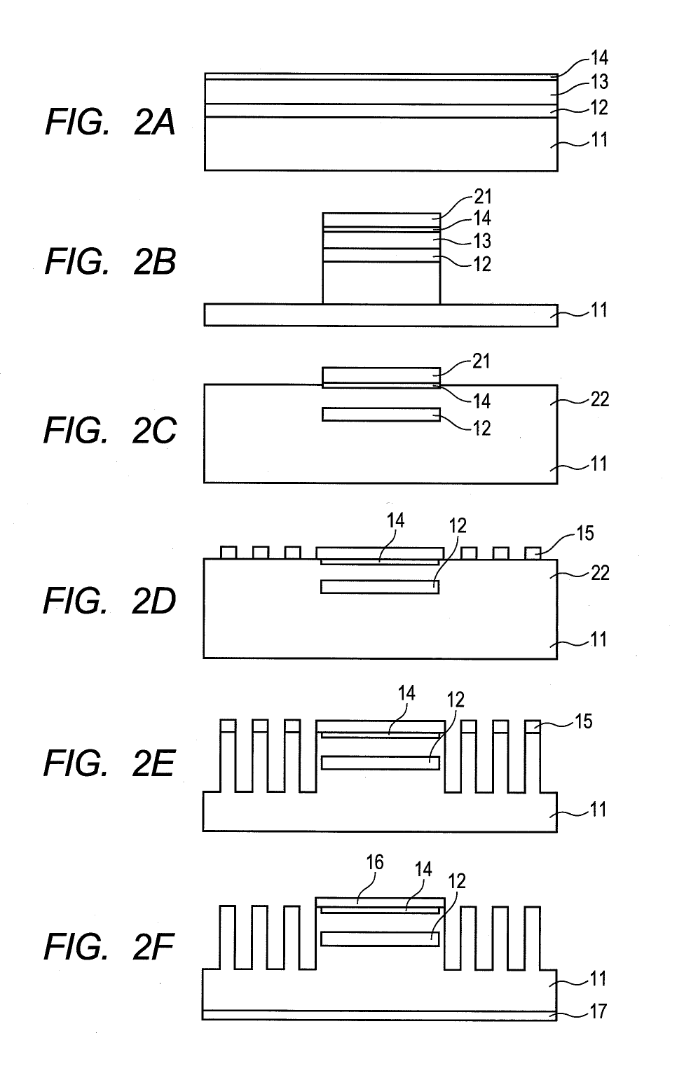

### DESCRIPTION OF EMBODIMENTS

Embodiments of the present invention will now be described in detail with reference to the accompanying drawings. Throughout the drawings for describing the embodiments, components having the same function are denoted by the same reference numeral and a repetitive description thereof will be omitted. Furthermore, in the drawings for describing the embodiments, hatching may be used even in top plan views so that the structure can be easily understood.

As used herein, the expression “optically smooth” is used to mean that “a flat surface has a characteristic of reflecting light in a regular manner.”

### First Embodiment

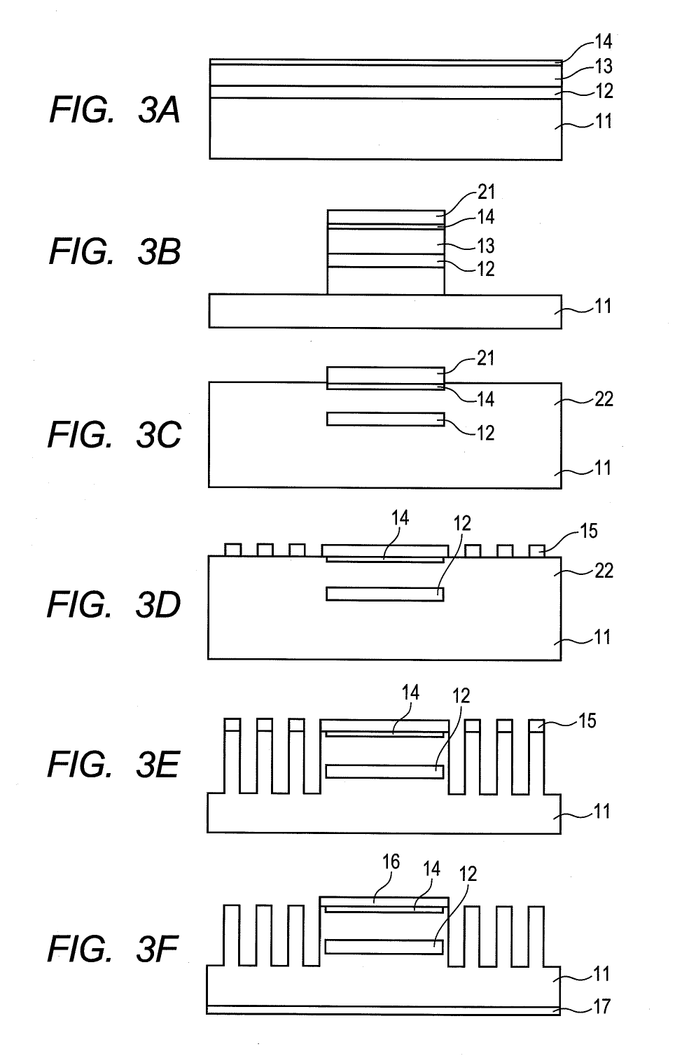

A first embodiment will be described with reference to FIG. 2. FIGS. 2(a) to 2(d) shows a process flow for fabricating a semiconductor laser using deeply-etched multilayer DBRs as the cavity mirrors according to the invention.

The present embodiment provides an exemplary 1.3 μm wavelength band laser having an InGaAlAs MQW active layer formed on an InP substrate. These figures show sectional views taken along the optical, axis direction of the laser element.

As shown in this process flow, an InGaAlAs MQW active layer 12 and two p-type semiconductor layers, i.e., a p-type InP cladding layer 13 and a p-type InGaAs contact layer 14, are first formed on an n-type InP substrate 11 (FIG. 2(a)). Here, the optical confinement layers provided to sandwich the active layer are layers for enhancing the optical confinement by the active layer. The optical waveguiding function can be effected by sandwiching the core region with the cladding layers having refractive indices lower than that of the core region. Therefore, the stacked structure of the cladding layer/active layer/cladding layer can achieve the optical waveguiding function. In view of this purpose, the refractive indices of the cladding layers are selected to fall below the refractive index of the optical confinement layer. Although in the present embodiment, the InP substrate 11 acts as the substrate-side cladding layer, it is of course also possible to provide a separate substrate-side cladding layer on the InP substrate 11.

Then, using a rectangular mask pattern 21 made of silicon dioxide, etching is performed up to below the InGaAlAs MQW active layer 12, thereby forming a stripe shaped mesa (FIG. 2(b)). Although in the present embodiment, a mesa shaped structure in which etching is performed up to below the active layer is employed, it is of course also possible to employ a ridge waveguide structure in which the semiconductor stack is etched only up to above the active layer. Thereafter, iron-doped semi-insulating InP 22 is grown on the exposed semiconductor substrate around the mesa shape, thereby forming a BH structure (FIG. 2(c)). Then, after the mask pattern 21 is removed, the ordinary thermal CVD and EB lithography are used to form a silicon dioxide mask pattern 15 having a width and spacing corresponding to three fourths the optical wavelength of light generated by the active layer 12 (FIG. 2(d)). Thereafter, using the dry etching technology, the semiconductor layer present in directions in which the mesa stripe extends is etched to a depth corresponding to below the active layer section, thereby forming a plurality of vertical grooves that extend perpendicular to a direction in which the substrate and the mesa extend. In this manner, reflectors having a reflective surface perpendicular to the mesa stripe are formed. The reflectors in the present embodiment are constituted by multilayer DBR mirrors consisting of semiconductor membranes and air layers (FIG. 2(e)). Finally, the silicon dioxide mask pattern 15 is removed, and a p-electrode 16 and an n-electrode 17 are formed by the ordinary resistance heating evaporation, thus resulting in the laser element being completed.

In the present embodiment, because the semiconductor membranes included in the multilayer DBR sections include no active layer and are made of a material with a band gap having a width that does not absorb the light output from the active layer, the amount of light absorbed by the multilayer DBR sections is reduced, thus resulting in the reflectivity being unlikely to be reduced. Furthermore, the portions of the multilayer DBRs that are adjacent to the active layer in directions in which the active layer extends, i.e., the portions on which the light output from the active layer is incident and that reflect the light, are formed only by a single semiconductor layer, i.e., a semiconductor layer made of an InP material in the present embodiment. Therefore, the surfaces of the semiconductor membranes, i.e., the shapes of the portions that reflect the light, have a uniform material composition. For this reason, vertical and optically smooth shapes can be obtained, thus enabling multilayer DBRs with little optical scattering to be obtained. Here, the semiconductor membranes are formed up to a level corresponding to the top surface of the cladding layer on the active layer. Because the cladding layer is a layer for enhancing the optical confinement by the active layer, the core region for optical waveguiding is below the level of the top surface of the cladding layer even if optical leakage is taken into consideration. Therefore, it is preferable that the semiconductor membranes included in the reflectors be formed up to a level corresponding to a position above the top surface of the cladding layer in order to further improve the reflectivity.

Even if after the dry etching, wet etching is performed to remove the layers damaged by the dry etching process, no irregularities due to the material composition are generated because the semiconductor membranes have a uniform material composition. Although in the present embodiment, InP having the same composition as the substrate except for the dopant is used for the semiconductor layer corresponding to the portions that reflect the light, it is also possible to use other semiconductor materials as long as the material composition is uniform.

In a variant of the present embodiment, it is also possible to employ a so-called window structure (FIG. 3(e)), i.e., a structure in which the grown semiconductor layer, i.e., the iron-doped semi-insulating InP 22 in this variant, is left between the sidewalls of the grooves and the active layer by changing the locations at which etching is performed to form the grooves. In this variant, because the ends of the active layer are embedded in semiconductor lattice-matched with the active layer and are therefore not in contact with air or dielectric surfaces, crystal defects are unlikely to be generated in the end portions of the active layer, thus enabling the reliability of the laser to be improved.

Although in the present embodiment, an example in which the invention is applied to a 1.3 μm wavelength band InGaAlAs laser formed on an InP substrate has been described, the substrate material, the active layer material, and the lasing wavelength are not limited to those disclosed in the present embodiment. The present invention is also applicable in a similar manner to laser elements made of other materials such as 1.5 μm band InGaAsP lasers, for example. Furthermore, although in the present embodiment, an example in which the invention is applied to an ordinary horizontal-cavity edge-emitting laser has been described, the laser structure is not limited to that disclosed in the present embodiment. The present invention is also applicable to, e.g., horizontal-cavity surface-emitting lasers, and is also applicable to integrated devices such as electroabsorption modulator integrated lasers in which an ordinary horizontal-cavity edge-emitting laser is monolithically integrated with an electroabsorption modulator. Furthermore, although in the present embodiment, an example in which the invention is applied to DBRs configured to have an optical length corresponding to three fourths the wavelength has been described, the invention is also applicable to lower or higher order DBRs configured to have an optical length corresponding to an integer multiple of one fourth the wavelength. Furthermore, although in the present embodiment, an example in which the invention is applied to multilayer DBRs consisting of semiconductor and air has been described, it is also possible, within the scope of the invention, to convert the multilayer DBRs consisting of semiconductor and air into multilayer DBRs consisting of semiconductor and dielectric by filling the air portions with a dielectric such as polyimide having a refractive index different from the semiconductor membranes.

### Second Embodiment

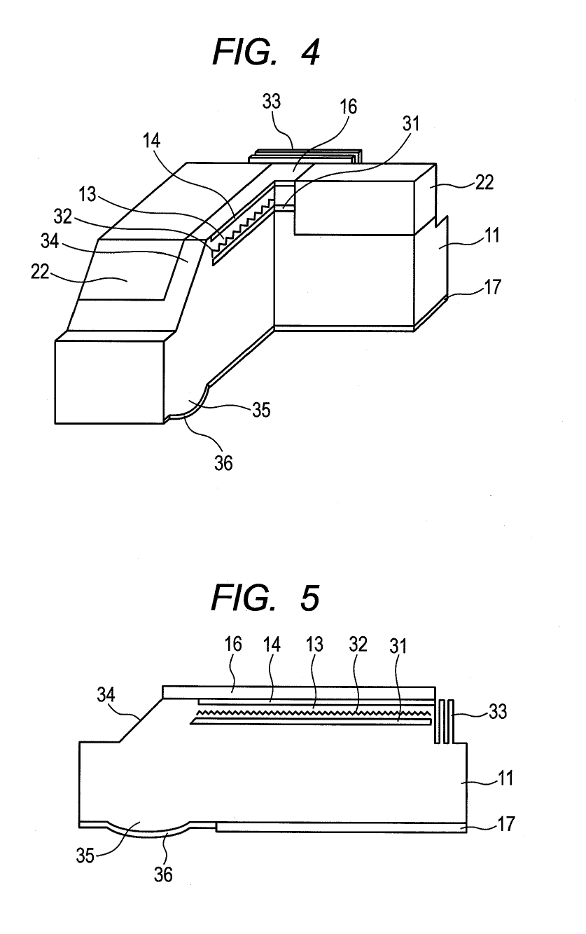

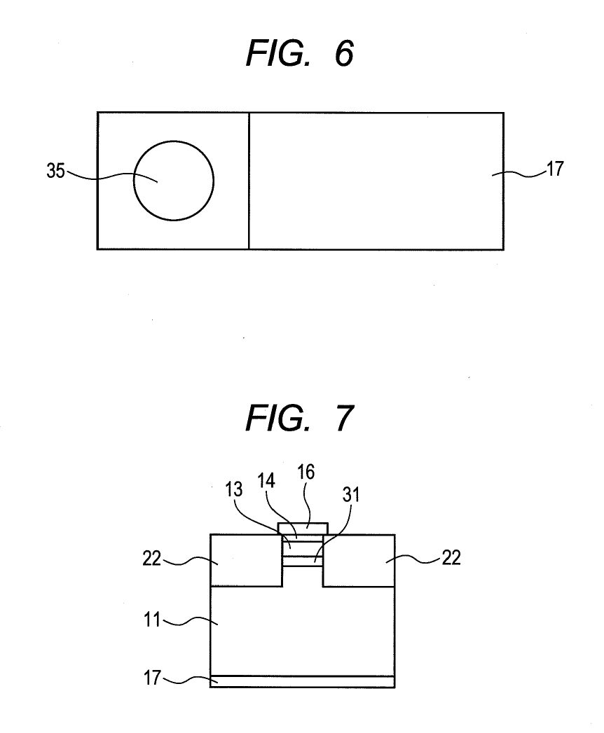

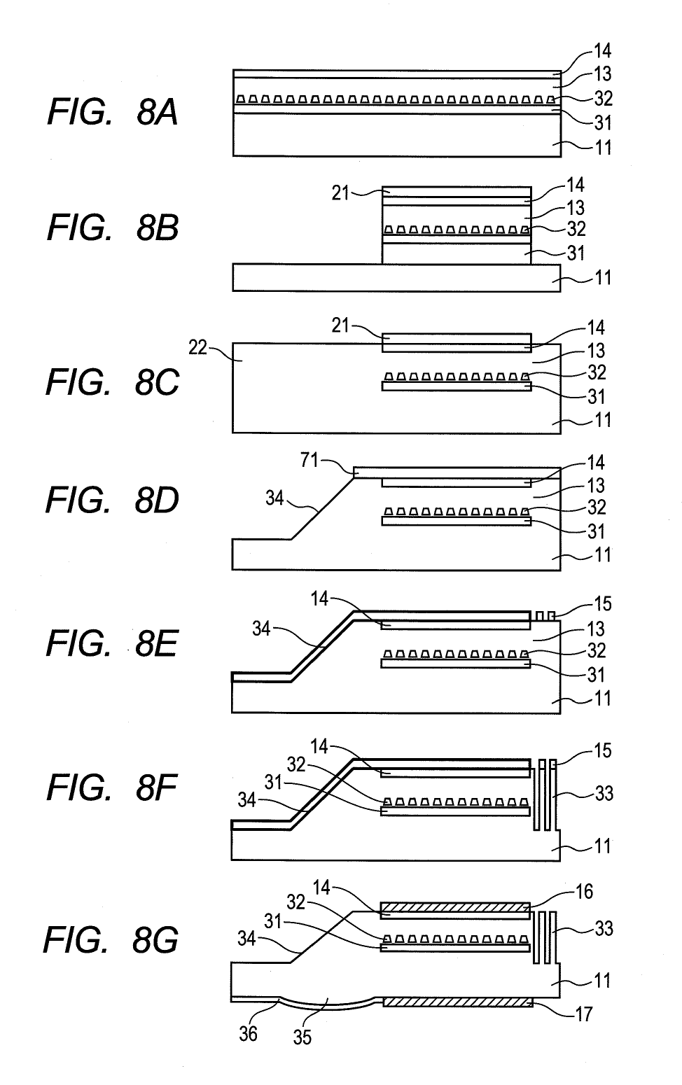

A second embodiment will be described with reference to FIGS. 4 to 8. In the present embodiment, the invention is applied to a 1.3 μm wavelength band horizontal-cavity surface-emitting distributed feedback (DFB) laser element having an InGaAlAs MQW active layer. FIG. 4 is a perspective view of the laser element with a part thereof broken away, FIG. 5 is a sectional view taken along the optical axis direction of the laser element, FIG. 6 is a bottom view of the laser element, FIG. 7 is a sectional view taken along a direction perpendicular to the optical axis of the laser element, and FIG. 8 shows sectional views showing a method for fabricating the laser element.

As shown in FIGS. 4 and 7, the optical waveguide section of the element is a stripe shaped mesa having a BH structure. Although in the present embodiment, a mesa shaped structure in which etching is performed up to below the active layer is employed, it is of course also possible to employ a ridge waveguide structure in which the semiconductor layer is etched only up to above the active layer. In this example, the mesa stripe shaped optical waveguide section having a BH structure is surrounded by an iron doped semi-insulating InP layer 22.

This laser element is formed on an n-type InP substrate 11. The active layer 31 is constituted by a structure in which an optical confinement layer made of n-type InGaAlAs, a strained MQW layer made of InGaAlAs, and an optical confinement layer made of p-type InGaAlAs are stacked. The quantum well layer that serves as the active region is formed by stacking five periods of a well layer having a thickness of 7 nm and a barrier layer having a thickness of 8 nm, and is designed so as to be able to achieve a laser having satisfactory characteristics. On these layers, a grating layer 32 made of an InGaAsP material is formed. The structure of the active layer 31 and the grating layer 32 is formed so that the DFB laser oscillates at a lasing wavelength of 1310 nm at room temperature. Furthermore, on the rear end surface of the element, a high reflectivity mirror 33 constituted by a deeply-etched multilayer DBR having two periods of InP and air is formed so as to extend in a direction perpendicular to the light output from the active layer. The InP portions have a thickness of 102 nm and the air portions have a groove width of 328 nm; these values correspond to the optical thickness of one fourth the wavelength of the light output from the active layer. Furthermore, the depth of the grooves is 4 μm, which corresponds to a depth of 2 μm below the active layer. Furthermore, on the laser light exit side, a total reflection mirror 34 is monolithically integrated so that the laser light is output through the bottom surface of the substrate. In addition, over the laser exit surface, a lens 35 is monolithically integrated, and the surface of the lens 35 is provided with an anti-reflection coating 36.

Here, the optical confinement layers provided to sandwich the quantum well layer are layers for enhancing the optical confinement by the quantum well layer. Because the optical waveguiding function is effected by sandwiching the core region with the cladding layers having a lower refractive indices than that of the core region, the stacked structure of the cladding layer/quantum well layer/cladding layer achieves the optical waveguiding function. Specifically, in order to enhance the optical confinement in the quantum well layer, the optical confinement layers are provided to sandwich the quantum well layer. The refractive indices of the cladding layers are, selected to fall below the refractive index of the optical confinement layer. Although in the present embodiment, the InP substrate 11 serves as the substrate-side cladding layer, it is of course also possible to provide a separate substrate-side cladding layer on the InP substrate 11.

Furthermore, the type of conductivity of the grating layer 32 is selected to be p-type. Such a structure is referred to as a refractive index coupled DFB laser because only the refractive index varies periodically in a direction in which the light travels. Although in the present embodiment, an example in which the grating is formed uniformly throughout the entire region of the DFB laser is described, it is also possible, as needed, to employ a so-called phase shift structure in which the grating is formed in a portion of the region with the phase of the grating shifted.

Next, a fabrication process according to the present embodiment will be described with reference to FIGS. 8(a) to 8(g). First, as shown in FIG. 8(a), in order to form the structure of the laser section, an active layer 31 is formed by stacking an optical confinement layer made of n-type InGaAlAs, a strained multiple quantum well layer made of InGaAlAs, and an optical confinement layer made of a p-type InGaAlAs on an n-type InP substrate 11. Then, on the active layer 31, a multi-layered structure including a grating layer 32 made of InGaAsP is formed. Furthermore, on this multi-layered structure, a cladding layer 13 made of p-type InP and a contact layer 14 made of p-type InGaAs are formed.

Next, as shown in FIG. 8(b), on the substrate having the above described multi-layered structure formed thereon, a mask pattern 21 made of silicon dioxide is formed. Then, using this mask pattern 21, a mesa stripe is formed by dry etching the contact layer 14, the p-type cladding layer 13, the grating layer 32, the active layer 31, and a portion of the InP substrate 11. The reactive ion etching method using chlorine gas is used for this etching process.

Next, the substrate is introduced into a crystal growth furnace, and as shown in FIG. 8(c), a buried hetero structure is formed by forming a semi-insulating InP layer 22 at 600° C. by the embedded growth process using the metal organic vapor phase epitaxy (MOVPE) method. The buried hetero-structure is a structure in which a material capable of confining light extends on both sides of the optical waveguide in a direction in which the light travels so as to sandwich the optical waveguide. In this example, iron doped high resistance semi-insulating InP 22 is used as the material used for the optical confinement. FIG. 7 referred above is a sectional view of the laser element taken along a plane orthogonal to a direction in which the light travels. This figure may enable the buried structure to be clearly understood. In the process for forming this buried structure, the semi-insulating InP layer 22 is also provided on the light exit end of the mesa stripe by the embedded growth process, simultaneously with the growth of the semi-insulating InP layer 22 on both sides of the optical waveguide in a direction in which the light travels.

Next, after the silicon dioxide film 21 used as the mask for the etching and selective growth processes is removed, as shown in FIG. 8(d), a silicon nitride film 71 is formed as an etching mask, thereby dry etching the semi-insulating InP layer 22 at an oblique angle of 45 degrees. The reactive ion beam etching method using chlorine and argon is used for this oblique dry etching process. In this manner, a total reflection mirror 34 having an angle of 45° with respect to the substrate surface, which is suitable for vertical output through the bottom surface of the substrate, is achieved. It is to be noted that the angle of the mirror need not necessarily be 45° as long as the mirror is oblique so that the vertical output through the bottom surface of the substrate can be achieved.

Next, after the silicon nitride film 71 is removed, as shown in FIG. 8(e), using the ordinary thermal CVD and EB lithography and the dry etching technology, a silicon dioxide mask pattern 15 is formed for forming a deeply-etched multilayer DBR corresponding to one fourth the wavelength. Thereafter, as shown in FIG. 8(f), using the dry etching method, the semiconductor layer present in a direction in which the mesa stripe extends is etched in a direction perpendicular to a direction in which the substrate and the mesa extend so that a plurality of grooves are formed with the semiconductor layer left between an end surface of the active layer and the grooves. As a result, a reflector having a reflective surface perpendicular to the mesa stripe is formed. The reflector in the present embodiment is constituted by a multilayer DBR 33 consisting of semiconductor membranes and air layers (FIG. 8(f)). Here, the reactive ion etching method using a mixture gas of ethane, hydrogen, and oxygen is used for this dry etching process, and the etching is performed up to a depth 2 μm below the position of the active layer 31. As a result, due to the advantage of the present embodiment in which the deeply-etched multilayer DBR is formed in the semiconductor layer made of only InP, a vertical and optically smooth shape was obtained as the shape of the grooves formed by the dry etching process. Furthermore, although after the dry etching process, a surface layer having a depth of about 10 nm was wet etched using concentrated sulfuric acid so as to remove the layer damaged by the dry etching process, almost no irregularities were created on the surface after the wet etching process, thus resulting in the vertical and optically smooth etched surface being kept. Furthermore, in the present embodiment, because the semiconductor membranes included in the multilayer DBR section include no active layer portions and are made of a material with a band gap energy that does not absorb the light output from the active layer, the light absorption amount was reduced, thus resulting in a multilayer DBR in which its reflectivity is unlikely to be reduced being obtained. Furthermore, in the present embodiment, the semiconductor membranes are formed up to a level corresponding to the top level of the cladding layer on the active layer. Because the cladding layer is a layer for enhancing the optical confinement by the active layer, the core region for optical waveguiding is below the top surface of the cladding layer even if optical leakage is taken into consideration. Therefore, in order to further improve the reflectivity, it is preferable that the semiconductor membranes of the reflector be formed up to a level corresponding to a position above the top surface of the cladding layer.

Next, as shown in FIG. 8(g), after the silicon dioxide mask 15 is removed, a p-electrode 16 is deposited on the contact layer 14 by the ordinary lift-off method, and a lens 35, an anti-reflection coating 36, and an n-electrode 17 are formed on the bottom surface, thus resulting in the laser element being completed. Although the end of the p-electrode 16 adjacent to the deeply-etched DBR is formed so as to correspond in position to the end of the p-type contact layer 14, the position of the end may be shifted in the optical axis direction by a small amount. In the present embodiment, because the deeply-etched multilayer DBR 33 is used as the high reflectivity mirror, the device length is not reduced even if the cavity length is reduced. For this reason, the resonator could be designed to have a short length of 100 μm. Because the element has a long length of 400 μm, the cleaving and handling of the element is easy even though the resonator has a short length of 100 μm.

The horizontal-cavity surface-emitting laser in the present embodiment had a threshold current of 2 mA and a slope efficiency of 0.6 W/A at room temperature under continuous wave (CW) operation, and exhibited oscillation characteristics characterized by a high slope efficiency at a low threshold current reflecting the short cavity structure and the high reflectivity rear end surface mirror according to the invention. In contrast, in the case of a reference laser element formed for illustrating the advantage of the present invention, in which the deeply-etched multilayer DBR section is formed by directly etching a portion including the active layer structure instead of the InP window region, the threshold current was 4 mA and the slope efficiency was 0.3 W/A; therefore, the threshold current was high and the slope efficiency was low when compared with the element having the structure according to the invention, thus resulting in the advantage of the invention being confirmed. Furthermore, a automatic power control operating test that was performed on the laser element according to the present embodiment at 50° C. and 5 mW showed an estimated life time of 1,000,000 hours, thus demonstrating the fact that the laser element according to the present embodiment is reliable reflecting the advantage of the invention due to its structure in which the end of the active layer is not exposed to air. In contrast, for the reference laser element in which the deeply-etched DBR is formed by directly etching the active layer, the estimated life time was 10,000 hours. Furthermore, because the entire laser fabrication process can be performed by wafer processes and the laser testing process also can be performed in a wafer state, the element could be fabricated at a low cost when compared with a laser of existing type in which a high reflectivity coating is provided over the cleaving surface.

Although in the present embodiment, an example in which the invention is applied to a 1.3 μm wavelength band InGaAlAs quantum well laser formed on an InP substrate has been described, the substrate material, the active layer material, and the lasing wavelength are not limited to those shown in the present embodiment. The invention is also applicable in a similar manner to a laser element consisting of other materials such as a 1.55 μm band InGaAsP laser, for example. Furthermore, although in the present embodiment, an example in which the invention is applied to a discrete horizontal-cavity surface-emitting laser has been described, the laser structure is not limited to that shown in the present embodiment. The invention is also applicable to, e.g., an ordinary horizontal-cavity edge-emitting laser, and is also applicable to an integrated device such as an electroabsorption modulator integrated laser in which an ordinary horizontal-cavity edge-emitting laser is monolithically integrated with an electroabsorption modulator. Furthermore, although in the present embodiment, an example in which the invention is applied to a DBR configured to have an optical length corresponding to one fourth the wavelength has been described, the invention is also applicable to a higher order DBR configured to have an optical length corresponding to three fourths the wavelength. Furthermore, although in the present embodiment, an example in which the invention is applied to a multilayer DBR consisting of semiconductor and air has been described, it is also possible, within the scope of the invention, to convert the multilayer DBR consisting of semiconductor and air into a multilayer DBR consisting of semiconductor and dielectric by filling the air portions with a dielectric such as polyimide having a refractive index different from the semiconductor membranes.

### Third Embodiment

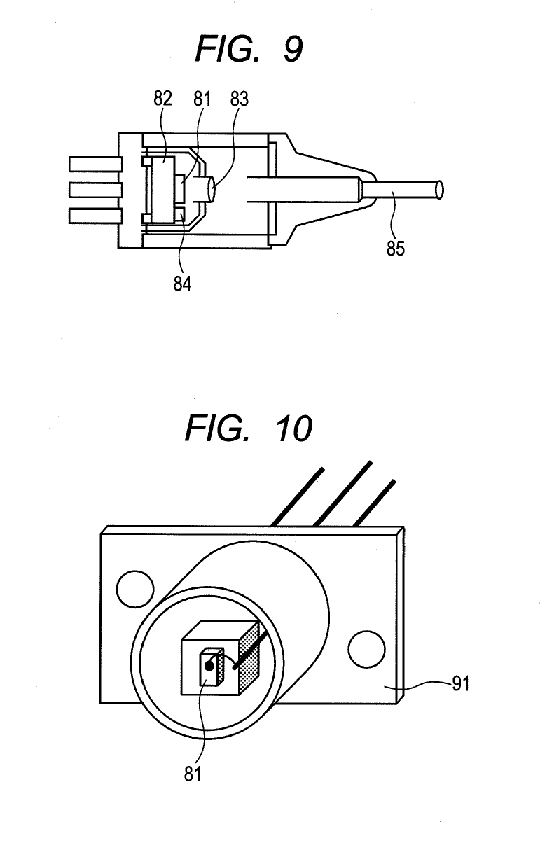

FIG. 9 is a structural diagram of an optical transmitter module in which a laser element 81 according to the second embodiment is first mounted to a heat sink 82, and then an optical lens 83, a photodiode 84 for monitoring the optical output at the rear end surface, and an optical fiber 85 are mounted integrally. Reflecting the high reflectivity mirror according to the present embodiment, the excellent characteristics, i.e., a threshold current of 2 mA and an oscillation efficiency of 0.5 W/A, were obtained at room temperature under continuous operating condition. Furthermore, reflecting the advantage of the present embodiment, the mass production of the element was easy, thus enabling the optical (transmission) module to be produced at a low cost.

FIG. 10 shows an example of a CAN-type module in which the laser element 81 according to the present embodiment is incorporated into a CAN-type package 91. A package formed by metallic mold pressing was used as the CAN-type module housing. Reflecting the advantage of the invention that the operating current of the semiconductor laser is low, a CAN-type module capable of operating at a low driving current was obtained.

### Fourth Embodiment

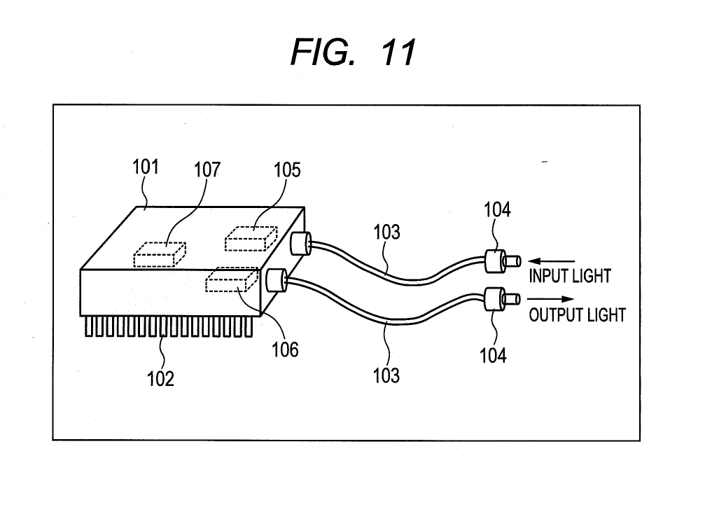

A fourth embodiment will be described with reference to FIG. 11. The present embodiment provides an exemplary optical (transmission/reception) module using the optical (transmission) module according to the third embodiment. The optical, transceiver module in the present embodiment includes an optical transceiver module housing 101, electric input/output pins 102, optical fibers 103, optical Connectors 104, an optical receiver module 105, an optical transmitter module 106, and a signal processing control unit 107, and has a function for converting a received optical signal into an electric signal and outputting the electric signal to the outside via the electric input/output pins 102 and also has a function for converting an electric signal input from the outside via the electric input/output pins 102 into an optical signal and transmitting the optical signal. The optical fibers 103 have one end connected to the optical transceiver module housing 101 and the other end connected to the optical connector 104. The optical connectors 104 have a structure that enables input light input from an external optical transmission path to be output to the optical fiber 103 and a structure that enables output light input from the optical fiber 103 to be output to an external optical transmission path, respectively. Reflecting the advantage of mounting the semiconductor laser having a small threshold current according to the invention, an optical transceiver module with less power consumption could be produced.

### LIST OF REFERENCE SIGNS

11 n-type InP substrate
12 InGaAlAs MQW active layer
13 p-type InP cladding layer
14 p-type InGaAs contact layer
15 silicon dioxide mask pattern
16 p-electrode
17 n-electrode
21 mask pattern
22 semi-insulating InP
31 active layer
32 grating layer
33 deeply-etched multilayer DBR
34 total reflection mirror
35 lens
36 anti-reflection coating
71 silicon nitride film
81 laser element
82 heat sink
83 optical lens
84 photodiode
85 optical fiber
91 CAN-type package
100 package
101 optical transceiver module housing,
102 electric input/output pin
103 optical fiber
104 optical connector
105 optical receiver module
106 optical transmitter module
107 signal processing control unit

1. A semiconductor laser element, comprising:
a semiconductor substrate;
a semiconductor stack formed over the semiconductor substrate and including an active layer and a cladding layer, at least a portion of the stack being formed as a stripe shaped mesa; and
a reflector provided over the semiconductor substrate in at least one of directions in which the mesa extends, characterized in that
the reflector includes a plurality of membranes having a thickness and arranged at an interval in a direction in which light output from the active layer travels, the thickness and the interval corresponding to an integer multiple of one fourth an optical wavelength of the light, and
at least a portion of the membranes that reflects the light has a band gap energy that does not absorb the light.

2. A semiconductor laser element, characterized by comprising:
a semiconductor substrate;
a stripe shaped mesa formed over the semiconductor substrate and having a semiconductor layer including an active layer; and
a reflector having a reflective surface perpendicular to a direction in which the mesa extends over the semiconductor substrate in at least one of directions in which the mesa extends, at least a portion of the reflector that reflects light output from the active layer including a plurality of membranes formed of a material with a band gap energy that does not absorb the light and arranged at an interval, a thickness of the membranes and the interval in a direction in which the light travels corresponding to an integer multiple of one fourth an optical wavelength, of the light.

3. The semiconductor laser element according to claim 2, characterized in that a portion of the membranes that reflects the light output from the active layer is optically smooth.

4. The semiconductor laser element according to claim 3, characterized in that the membranes are formed of a semiconductor material.

5. The semiconductor laser element according to claim 4, characterized in that the membranes are formed of a semi-insulating material.

6. The semiconductor laser element according to claim 2, characterized in that in the mesa, at least one end of the active layer which faces the reflector is embedded in a material that is lattice-matched with the active layer.

7. The semiconductor laser element according to claim 2, characterized in that at one end of the mesa, a mirror having an reflective surface oblique with respect to the substrate surface for outputting the light in a direction perpendicular to the semiconductor substrate is provided.

8. The semiconductor laser element according to claim 7, characterized in that the semiconductor substrate is provided with a lens over an exit aperture through which the light reflected by the oblique mirror is output.

9. The semiconductor laser element according to claim 2, characterized in that space between the membranes is filled with a material that is different in refractive index from the membranes.

10. The semiconductor laser element according to claim 2, characterized in that
the mesa includes a cladding layer and a contact layer over the active layer, and
the membranes are formed up to a level corresponding to above an upper surface of the cladding layer.

11. An optical module, characterized by comprising:
a heat sink;
a semiconductor laser element according to claim 2 disposed on the heat sink;
a photodiode disposed on the heat sink in a position in which light in one of directions in which the semiconductor laser element outputs can be received; and
and optical lens disposed in a direction in which light output from the semiconductor laser element travels.

12. A method for fabricating a semiconductor laser element, characterized by comprising the steps of:
sequentially stacking a first semiconductor layer, an active layer, and a second semiconductor layer over a semiconductor substrate;
exposing the first semiconductor layer or the semiconductor substrate such that a mesa stripe including the stacked layers up to the first semiconductor layer is formed;
re-growing a semiconductor layer not including the active layer on the exposed first semiconductor layer or semiconductor substrate in a direction in which the mesa stripe extends; and
forming a groove in the re-grown semiconductor layer at an interval corresponding to an integer multiple of one fourth an optical wavelength of light output from the active layer such that the regrown semiconductor layer is left between the active layer and the groove.

13. The method for fabricating a semiconductor laser according to claim 12, characterized in that the groove formed in the semiconductor layer is filled with a material that is different in refractive index from the semiconductor layer.
